(19) United States
(12) Patent Application Publication
(10) Pub. No.: US 2010/0075498 A1
(43) Pub. Date: Mar. 25, 2010

(54) SEMICONDUCTOR DEVICE AND METHOD FOR MANUFACTURING THE SAME, AND PROCESSING LIQUID

(76) Inventors: Daisuke TAKAGI, Tokyo (JP); Xinming Wang, Tokyo (JP); Akira Owatari, Tokyo (JP); Akira Fukunaga, Tokyo (JP); Akihiko Tashiro, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 12/629,332

(22) Filed: Dec. 2, 2009

Related U.S. Application Data
(62) Division of application No. 11/663,351, filed on Oct. 9, 2007, now abandoned.

(30) Foreign Application Priority Data
Sep. 22, 2004 (JP) 2004-276109

(51) Int. Cl. H01L 21/3205

(52) U.S. Cl. 438/678; 257/E21.295

(57) ABSTRACT

A semiconductor device has interconnects protected with an alloy film having a minimum thickness necessary for producing the effect of preventing diffusion of oxygen, copper, etc., formed more uniformly over an entire surface of a substrate with less dependency to the interconnect pattern of the substrate. The semiconductor device includes, embedded interconnects, formed by filling an interconnect material into interconnect recesses formed in an electric insulator on a substrate, and an alloy film, containing 1 to 9 atomic % of tungsten or molybdenum and 3 to 12 atomic % of phosphorus or boron, formed by electroless plating on at least part of the embedded interconnects.

This application is a Divisional of U.S. application Ser. No. 11/663,351, filed Oct. 9, 2007, which is the National Stage of International Application No. PCT/JP2005/018049, filed Sep. 25, 2005, the entire contents of each of which are herein incorporated by reference.

### TECHNICAL FIELD

The present invention relates to a semiconductor device and a method for manufacturing the same, and more particularly to a semiconductor device and the same having a conductive film, which has a function of preventing thermal diffusion of an interconnect material into an interlevel dielectric film or a function of enhancing adhesion between interconnects and an interlevel dielectric film, on bottoms and sides surfaces or exposed surfaces of embedded interconnects of an interconnect material (conductive material), such as copper or silver, embedded in interconnect recesses provided in a surface of a substrate, such as a semiconductor wafer, or having an interconnect protective film, such as a magnetic film, for covering the interconnects.

The present invention also relates to a processing liquid useful for manufacturing such a semiconductor device.

### BACKGROUND ART

As an interconnect formation process for semiconductor devices, there is getting employed a process (so-called damascene process) in which an interconnect material (conductive material) is embedded in interconnect recesses, such as trenches, via holes, or the like. This process includes embedding aluminum or, recently, metal such as copper, silver or an alloy thereof in interconnect recesses such trenches, via holes, or the like, which have previously been formed in an interlevel dielectric film, and then removing excessive metal by chemical mechanical polishing (CMP) so as to flatten a surface of the substrate.

Conventionally, in the case of such interconnects, for example, copper interconnects, which use copper as an interconnect material, there has been employed a method in which a barrier layer is formed on bottom surfaces and side surfaces of the interconnects to prevent thermal diffusion of the interconnects (copper) into an interlevel dielectric film and to improve electromigration resistance of the interconnects so as to improve the reliability, or a method in which an oxidation resistant film is formed to prevent oxidation of the interconnects (copper) under an oxidizing atmosphere so as to produce a semiconductor device having a multi-level interconnect structure in which insulating films (oxide films) are subsequently laminated. Conventionally, metal such as tantalum, titanium, tungsten or ruthenium, or nitride thereof has heretofore been used as this type of barrier layer. Nitride of silicon or silicon carbide has generally been used as an oxidation resistant film.

As copper interconnects become finer and the current density becomes higher, current oxidation resistant films sometimes cannot ensure sufficient reliability of interconnects. Therefore, to take place of or to be added to an oxidation resistant film, the use of an interconnect protective film composed of a cobalt alloy, a nickel alloy, or the like, which selectively covers the bottom and side surfaces, or exposed surfaces of embedded interconnects to prevent thermal diffusion, electromigration and oxidation of the interconnects, is presently being studied. With regard to nonvolatile magnetic memories, current density in copper interconnects increases as memory cells become denser and the design rule becomes smaller, which can cause the problem of electromigration. Further, as memory cells become smaller, adjacent cells become closer and writing current in memory cells increases, whereby cross talk is more likely to occur. Prevention of cross talk is therefore a significant problem. A yoke structure, comprising copper interconnects and a magnetic film of cobalt alloy, nickel alloy, or the like, encircling the interconnects, is considered to be effective for solving the above problems. Such a magnetic film can be obtained by, for example, electroless plating.

As shown in FIG. 1, for example, interconnect recesses 4 are formed in an insulating film 2 of SiO₂ or the like which has been deposited on a surface of a substrate W, such as a semiconductor wafer. A barrier layer 6 of TaN or the like is formed on the surface, and then copper plating, for example, is carried out onto the surface of the substrate W to fill the interconnect recesses 4 with copper and deposit copper film on the surface of the substrate W. Thereafter, CMP (chemical mechanical polishing) is carried out onto the surface of the substrate W so as to flatten the surface of the substrate, thereby forming interconnects 8 composed of a copper film in the insulating film 2. Thereafter, an interconnect protective film (cap material) 9 composed of a CoWP alloy is formed, e.g., by electroless plating selectively on the surfaces of interconnects (copper film) 8 to the protect the interconnects 8.

There will be described a process of forming an interconnect protective film (cap material) 9 of such a CoWP alloy selectively on surfaces of interconnects 8 by using a conventional electroless plating method. First, the substrate W, such as a semiconductor wafer, which has been carried out a CMP process, is immersed, for example, in dilute sulfuric acid having an ordinary temperature for about one minute to remove, e.g., a metal oxide film of interconnect metal formed on the surfaces of interconnects. After the surface of the substrate W is cleaned with a cleaning liquid, such as pure water, the substrate W is immersed, for example, in a PdCl₂/HCl mixed solution having an ordinary temperature for about one minute to adhere Pd as a catalyst to the surfaces of interconnects 8 so as to activate exposed surfaces of interconnects 8. After the surface of the substrate W is cleaned (rinsed) with pure water or the like, the substrate W is immersed, for example, in a CoWP plating solution at the solution temperature of 80° C. for about 120 seconds to carry out electroless plating selectively on the surfaces of activated interconnects 8. Thereafter, the surface of the substrate W is cleaned with a cleaning liquid, such as pure water. Thus, an interconnect protective film 9 made of a CoWP alloy film is formed selectively on the exposed surfaces of interconnects 8 so as to protect the interconnects 8.

### DISCLOSURE OF INVENTION

An interconnect protective film (cap material) of CoWP alloy, formed by electroless plating, is sometimes required to function as an oxidation resistant film or as a copper diffusion-preventing film, as described above. In order to obtain such a function, it is necessary to make an interconnect protective film thick to some extent. A too thick interconnect protective film, however, will adversely affect the intended lowering of resistance by the use of copper interconnects. There is a correlation between the rate of supply of a material and the rate of plating in electroless plating, and the rate of plating depends on, e.g., the width and the density of distribution of the interconnect pattern of a substrate. Thus, a plated film (alloy film) tends to be thicker in a region with a sparse interconnect pattern than in a region with a dense interconnect pattern, for example. A demand therefore exists for the formation of an interconnect protective plated film (alloy film), having a more uniform thickness over an entire surface of a substrate, without depending on the density, etc. of the interconnect pattern of the substrate.

The present invention has been made in view of the above situation. Thus, it is an object of the present invention to provide a semiconductor device which has interconnects protected with an alloy film having a minimum thickness necessary for producing the effect of preventing diffusion of oxygen, copper, etc., formed more uniformly over an entire surface of a substrate with less dependency to the interconnect pattern of the substrate, and to provide a method for manufacturing the semiconductor device, and a processing solution for use in the manufacturing of the semiconductor device.

In order to achieve the object, the present invention provides a semiconductor device comprising, embedded interconnects, formed by filling an interconnect material into interconnect recesses formed in an electric insulator on a substrate, and an alloy film, containing 1 to 9 atomic % of tungsten or molybdenum and 3 to 12 atomic % of phosphorus or boron, formed by electroless plating on at least part of the embedded interconnects.

An alloy film, containing W (tungsten) or Mo (molybdenum) in an amount of 1 to 9 atomic %, can be formed by electroless plating with a more uniform thickness over an entire surface of a substrate while reducing a difference in the material supply rate upon reaction and thus in the film-forming rate, caused by the density, etc. of the interconnect pattern of the substrate. Thus, it becomes possible to protect, e.g., interconnects with an alloy film which has been formed more uniformly over an entire surface of a substrate with less dependency to the interconnect pattern. Furthermore, the inclusion of W or Mo in the alloy film can increase the thermal stability of the alloy film and can prevent impurities, such as oxygen and copper, from permeating and diffusing through the alloy film.

Because of the inclusion of 3 to 12 atomic % of P (phosphorus) or B (boron) in the alloy film, the alloy film becomes amorphous or microcrystalline. This makes it possible to form, by electroless plating, an alloy film having good surface roughness with little influence of the orientation of an underlying base. Further, there are cases where the P or B component restricts the movement of impurities in the alloy film or the phosphorus combines with an impurity or an interconnect metal, e.g., copper, whereby they are stabilized. This can prevent diffusion of the impurities and the interconnect metal.

In a preferred aspect of the present invention, the alloy film is formed selectively on exposed surfaces of the embedded interconnects.

By selectively covering exposed surfaces of the interconnects with the alloy film to protect the interconnects, deterioration of the interconnects, such as by oxidation, due to their exposure to the air can be prevented. Furthermore, the alloy film can enhance the adhesion between the interconnects and an insulating film, such as an oxidation resistant film, to be superimposed on the alloy film. Current oxidation resistant films are generally formed of SiN, SiC, or the like, having a somewhat high dielectric constant of 4 to 7. By forming the alloy film selectively on the exposed surfaces of interconnects, it becomes possible to use, instead of SiN, SiC or the like, a material which may be somewhat poorer in the ability to prevent oxidation, but has a low dielectric constant, for an oxidation resistant film. It also becomes possible, in some instances, to eliminate an oxidation resistant film and superimpose an interlevel dielectric film directly on the alloy film, thereby further lowering the effective dielectric constant between interconnects.

The alloy film may be formed on bottom and side surfaces of the recess for embedded interconnects.

A film of Ti, Ta, W, Ru or a nitride thereof, or a silicon nitride as formed by PVD, CVD or ALD is chiefly employed currently as a thermal diffusion preventing film formed on the bottom and side surfaces of interconnects. By using, as a thermal diffusion preventing film, the present alloy film formed by electroless plating which is a wet processing, it becomes possible to eliminate a vacuum evacuation equipment, etc., thereby reducing an equipment investment. Further, when using a wet processing to fill an interconnect material into interconnect recesses in the formation of embedded interconnects, the formation of the interconnects and the formation of the alloy film can be carried out successively, facilitating the process control.

In a preferred aspect of the present invention, the interconnect material is copper, a copper alloy, silver, a silver alloy, gold or a gold alloy.

Semiconductor devices, for which protection of interconnects with an alloy film as formed by electroless plating is required, generally are highly-integrated ones.

Speeding-up and higher integration of semiconductor devices can be achieved by using, among various possible interconnect metals, copper, a copper alloy, silver, a silver alloy, gold or a gold alloy as an interconnect material for highly-integrated semiconductor devices.

The present invention also provides a method for manufacturing a semiconductor device, comprising: carrying out pre-plating processing on a surface of a base; and forming an alloy film by bringing a processing solution for electroless plating into contact with the surface of the base after the pre-plating processing, said processing solution having a pH of 8.0 to 9.5 and comprising nickel or cobalt, tungsten or molybdenum, and a phosphorus- or boron-containing reducing agent in a molar concentration ratio of 1:(0.5 to 4.0):(1 to 15).

The present method allows the resulting alloy film, deposited by plating reaction, to contain W or Mo in an amount of 1 to 9 atomic %. This can reduce a difference in the material supply rate, caused by the density, etc. of the interconnect pattern of the substrate, during the plating reaction, thus reducing a difference in the film-forming rate and, in addition, increase the thermal stability of the alloy film and prevent impurities, such as oxygen and copper, from permeating and diffusing through the alloy film.

The present method also allows the resulting alloy film, deposited by the plating reaction, to contain P or B in an amount of 3 to 12 atomic %. The presence of P or B in such an amount around Co or Ni can prevent impurities from diffusing out of the alloy film, enabling the alloy film to function as an oxidation resistant film or an interconnect metal diffusion-preventing film. There is a case where the alloy film forms a compound with an impurity. This increases the function of the alloy film, e.g., as an oxidation resistant film.

Preferably, the pre-plating processing is carried out on surfaces of embedded interconnects as the base, formed by filling an interconnect material into interconnect recesses formed in an electric insulator on a substrate.

Preferably, the content of sodium in the processing solution is not more than 1 g/L.

In general, components of an electroless plating solution are used in the form of an alkali metal salt or an ammine salt, and an aqueous solution of KOH, NaOH, Ca(OH)₂, ammonia or an organic alkali, as typically exemplified by TMAH (tetramethylammonium hydroxide), is used as a pH adjustment agent. Sodium, when it diffuses into a semiconductor element, can change the properties of the semiconductor element. Further, as compared to, e.g., potassium, sodium is more likely to form a stable complex with a counter ion, whereby a deposit is likely to be produced when the solution temperature is lowered (the solubility of the complex is low). A stable process is possible by making the content of such sodium in the present processing solution for use in electroless plating not more than 1 g/L, for example, by using potassium instead.

Preferably, the content of ammonia or a salt thereof and/or an organic alkali or a salt thereof in the processing solution is not more than 0.1 mol/L.

In general, components of an electroless plating solution are used in the form of an alkali metal salt or an ammine salt, and an aqueous solution of KOH, NaOH, Ca(OH)₂, ammonia or an organic alkali, as typically exemplified by TMAH, is used as a pH adjustment agent. Ammonia, however, forms a stable complex with a metal in the plating solution, which retards the initiation of reaction and eventually shortens the life of the plating solution. Further, the volatility of ammonia may require a troublesome control of the solution. A stable process becomes possible by making the content of ammonia or a salt thereof and/or an organic alkali or a salt thereof in the present processing solution for use in electroless plating not more than 0.1 mol/L, and using, e.g., potassium as a counter ion.

Preferably, the temperature of the processing solution upon contact with the surface of the base is 50 to 90° C.

By thus bringing the processing solution at 50 to 90° C. into contact with the surface of the base, the reactivity of the processing solution can be made constant, whereby an alloy film (plated film) having excellent in-plane thickness uniformity can be obtained. The temperature of the processing solution is more preferably 60 to 75° C.

The present invention also provides a processing solution having a pH of 8.0 to 9.5, comprising nickel or cobalt, tungsten or molybdenum, and a phosphorus- or boron-containing reducing agent in a molar concentration ratio of 1:(0.5 to 4.0):(1 to 15).

Preferably, the content of sodium in the processing solution is not more than 1 g/L.

Preferably, the content of ammonia or a salt thereof and/or an organic alkali or a salt thereof in the processing solution is not more than 0.1 mol/L.

Preferably, the processing solution contains a citrate or a tartrate, and boric acid or a tetraborate.

By using, as a complexing agent for a metal, a citrate or a tartrate, i.e., a carboxylic acid, which does not contain ammonia in a large portion, a complex, when heated continuously, can be prevented from changing its form, enabling stable deposition. Boric acid or a tetraborate shows a pH buffering action at a reaction interface in a bath in which ammonia is little present. The use of boric acid or a tetraborate in the processing solution can therefore provide a stable plating reaction.

Preferably, the citrate or the tartrate has potassium as a counter ion, and the tetraborate also has potassium as a counter ion.

A citrate, etc., having sodium as a counter ion, generally has a low solubility and can possibly be crystallized in the processing solution. A citrate, etc., having ammonia as a counter ion, generally has a low boiling point, and thus can vaporize when the solution is heated. A troublesome control of the processing solution is therefore needed. On the other hand, the use of potassium as a counter ion of a citrate, etc. makes it possible to carry out stable plating with good reproducibility.

Preferably, the processing solution further contains a hypophosphite.

Phosphinic acid (hypophosphorous acid) in an electroless plating solution principally acts as a reducing agent. DMAB (dimethylamine borane) and hydrazine are generally known as a reducing agent for electroless plating. DMAB and hydrazine are, however, generally poor in the stability in a plating solution, which may shorten the life of the solution. Phosphinic acid, on the other hand, is relatively stable in a plating solution. Thus, the use of phosphinic acid as a reducing agent can extend the life of the solution.

Preferably, the hypophosphite is an aqueous solution of phosphinic acid whose counter ion is hydrogen ion.

Sodium phosphinate and ammonium phosphinate are generally known as a salt to supply phosphinate (hypophosphite) ion. As described above, these salts have the solubility and semiconductor contamination problems (with sodium) and the problem of the life of bath (with ammonia). The use of an aqueous solution of phosphinic acid (phypophosphorous acid) H₃PO₂, which does not contain a counter ion (whose counter ion is hydrogen ion), can prepare a bath that can deal with the above problems.

According to the present invention, interconnects can be protected with an alloy film, having a minimum thickness necessary for preventing diffusion of oxygen, copper, etc., which has been formed with a more uniform thickness over the entire surface of a substrate with less dependency to the interconnect pattern.

### BRIEF DESCRIPTION OF DRAWINGS

FIG. 1 is a cross-sectional diagram illustrating an interconnect protective film as formed by electroless plating;

FIGS. 2A through 2C are diagrams illustrating, in a sequence of process steps, a process of manufacturing a semiconductor device up to a CMP step to complete the formation of copper interconnects;

FIGS. 3A through 3C are diagrams illustrating, in a sequence of process steps, a process of manufacturing a semiconductor device according to an embodiment of the present invention after the CMP step;

FIG. 4 is a plan view showing the layout of a semiconductor manufacturing apparatus;

FIG. 5A is a plan view showing an isolated interconnect formed in a sample used in Examples, and FIG. 5B is a plan view showing a dense interconnect formed in the sample used in Examples; and

FIG. 6A is a cross-sectional diagram schematically showing an alloy film formed on the surface of the isolated interconnect in Examples, and FIG. 6B is a cross-sectional diagram schematically showing an alloy film formed on the surface of the dense interconnect in Examples.

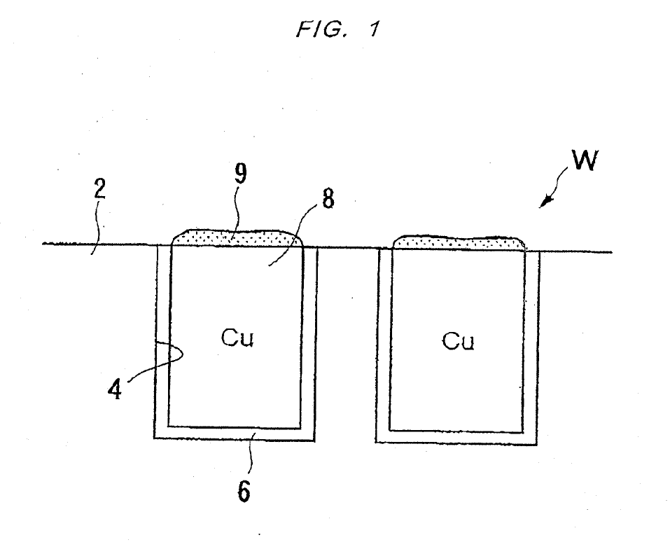

### BEST MODE FOR CARRYING OUT THE INVENTION

Preferred embodiments of the present invention will now be described with reference to the drawings. The following description illustrates the case of selectively covering exposed surfaces of copper interconnects as a plating base with an interconnect protective film (cap material) of CoWP alloy to protect the interconnects (plating base) with the interconnect protective film (alloy film).

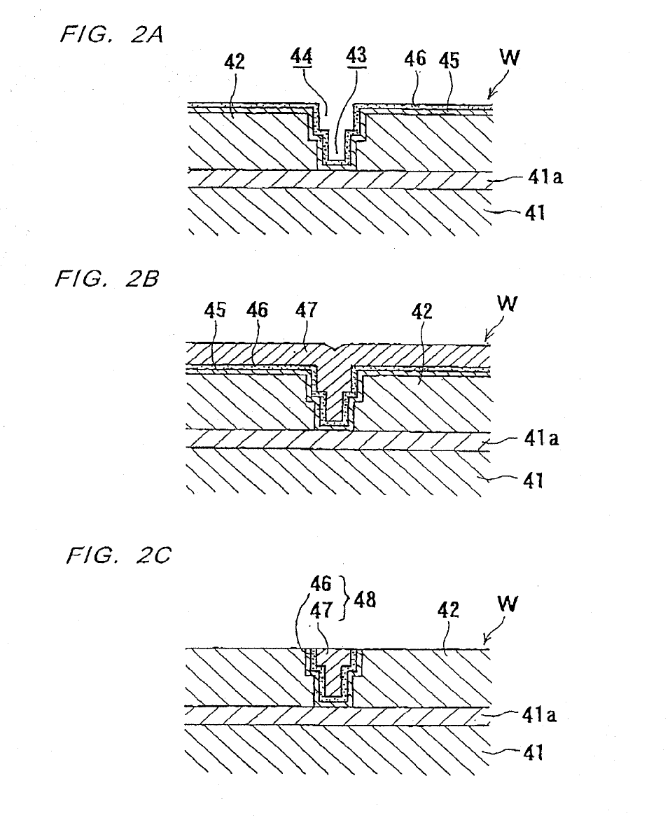

FIGS. 2A through 2C illustrate, in a sequence of process step, a process of manufacturing a semiconductor device up to a CMP step to complete the formation of copper interconnects. First, as shown in FIG. 2A, an insulating film (interlevel dielectric film) 42, for example, an oxide film of SiO₂ or a film of a low-k material, is deposited on a conductive layer 41a with semiconductor elements formed therein, formed on a semiconductor base 41. Via holes 43 and trenches 44 as interconnect recesses are formed in the insulating film 42, for example, by the lithography/etching technique. Thereafter, a barrier layer 45 of TaN, or the like, is formed on the insulating film 42, and a seed layer 46, which serves as a feeding layer in electroplating, is formed on the barrier layer 45, for example, by sputtering.

Thereafter, as shown in FIG. 2B, copper plating of the surface of the substrate W is carried out to fill the via holes 43 and the trenches 44 with copper, and, at the same time, deposit a copper film 47 on the insulating film 42. Thereafter, the barrier layer 45, the seed layer 46 and the copper film 47 on the insulating film 42 are removed, for example, by chemical mechanical polishing (CMP) so as to make the surface of the copper film 47, embedded in the via holes 43 and the trenches 44, substantially flush with the surface of the insulating film 42. Interconnects (copper interconnects) 48 composed of the seed layer 46 and the copper film 47 are thus formed in the insulating film 42, as shown in FIG. 2C.

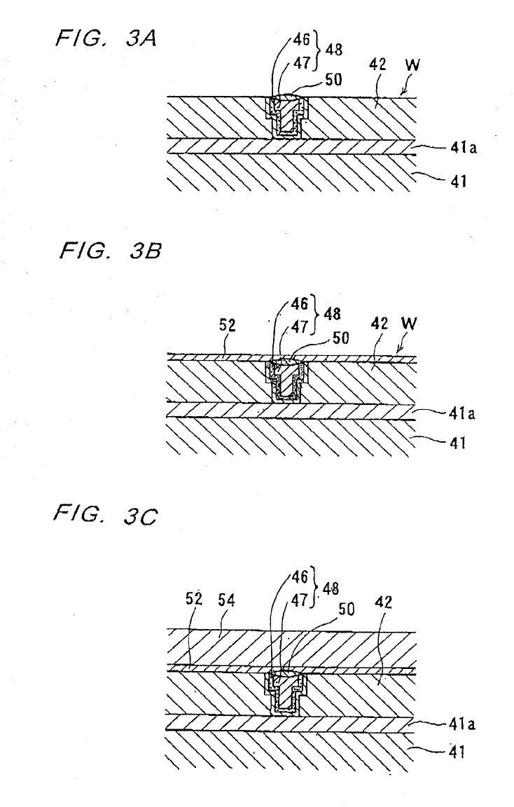

A semiconductor device according to the present invention is manufactured by forming an interconnect protective film 50 of CoWP alloy selectively on exposed surfaces of thus-formed interconnects 48, as shown in FIG. 3A, for protecting the interconnects 48. Further, as shown in FIG. 3B, an oxidation resistant film 52 of SiN, SiC, or the like, is formed on the surface of the substrate W. Thereafter, as shown in FIG. 3C, an insulating film (interlevel dielectric film) 54 of SiO₂, SiOF, or the like, is formed on a surface of the oxidation resistant film 52, forming a multi-level interconnect structure.

In this embodiment, the interconnect protective film 50 is composed of a CoWP alloy containing 1 to 9 atomic % of W (tungsten) and 3 to 12 atomic % of P (phosphorus). A CoWP alloy film, containing W in an amount of 1 to 9 atomic %, can be formed by electroless plating with a more uniform thickness over an entire surface of the substrate W while reducing a difference in the material supply rate upon reaction and thus in the film-forming rate, caused by the density, etc. of the interconnect pattern of the substrate W. Thus, it is possible to selectively cover exposed surfaces of interconnects 48 and protect the interconnects 48 with the interconnect protective film (alloy film) 50 which has been formed more uniformly over the entire surface of the substrate W with less dependency to the interconnect pattern. Furthermore, the inclusion of W in the interconnect protective film 50 can increase the thermal stability of the interconnect protective film 50, and can prevent impurities, such as oxygen and copper, from permeating and diffusing through the interconnect protective film 50.

ICP emission spectrometry, for example, can be used for compositional analysis of the alloy film.

Because of the inclusion of 3 to 12 atomic of P in the CoWP alloy film, the alloy film becomes amorphous or microcrystalline. This makes it possible to form, by electroless plating, the interconnect protective film 50 having good surface roughness with little influence of the orientation of the underlying interconnects 48. Further, there are cases where the P component restricts the movement of impurities in the interconnect protective film 50 or the phosphorus combines with an impurity or an interconnect metal, e.g., copper, whereby they are stabilized. This can prevent diffusion of the impurities and the interconnect metal.

By thus selectively covering the exposed surfaces of interconnects 48 with the interconnect protective film 50 of CoWP alloy to protect the interconnects 48, deterioration of the interconnects 48 such as by oxidation due to their exposure to the air can be prevented. Furthermore, the interconnect protective film 50 can enhance the adhesion between the interconnects 48 and an insulating film, such as an oxidation resistant film 52, to be superimposed on the interconnect protective film 50. In this embodiment, the oxidation resistant film 52 is formed of SiN, SiC, or the like, having a somewhat high dielectric constant of 4 to 7. By forming the interconnect protective film (alloy film) 50 selectively on the exposed surfaces of interconnects 48, it becomes possible to use, instead of SiN, SiC or the like, a material which may be somewhat poorer in the ability to prevent oxidation, but has a low dielectric constant, for the oxidation resistant film 52. It also becomes possible, in some instances, to eliminate the oxidation resistant film 52 and superimpose an insulating film (interlevel dielectric film) 54 directly on the alloy film 50, thereby further lowering the effective dielectric constant between the interconnects 48.

Though, in this embodiment, the interconnect protective film 50 is composed of a CoWP alloy, it is also possible to use Ni instead of Co, Mo (molybdenum) instead of W, and B (boron) instead of P, respectively.

In this embodiment, the barrier layer 45 of TaN or the like is formed on bottom and side surfaces of the recess for interconnects 48. It is also possible to use the same CoWP alloy film as described above, formed by electroless plating, also as the barrier layer 45. By using, as the barrier layer 45 as a thermal diffusion preventing film, the CoWP alloy film formed by electroless plating which is a wet processing, it becomes possible to eliminate a vacuum evacuation equipment, etc., thereby reducing an equipment investment. Further, when using a wet processing, such as electroplating, to fill an interconnect material into interconnect recesses in the formation of embedded interconnects, the formation of the interconnects and the formation of the alloy film can be carried out successively, facilitating the process control.

Besides copper, a copper alloy, silver, a silver alloy, gold or a gold alloy may be used as an interconnect material. Semiconductor devices, for which protection of interconnects with an alloy film as formed by electroless plating is required, generally are highly-integrated ones. Speeding-up and higher integration of semiconductor devices can be achieved by using, among various possible interconnect metals, copper, a copper alloy, silver, a silver alloy, gold and a gold alloy as an interconnect material for highly-integrated semiconductor devices.

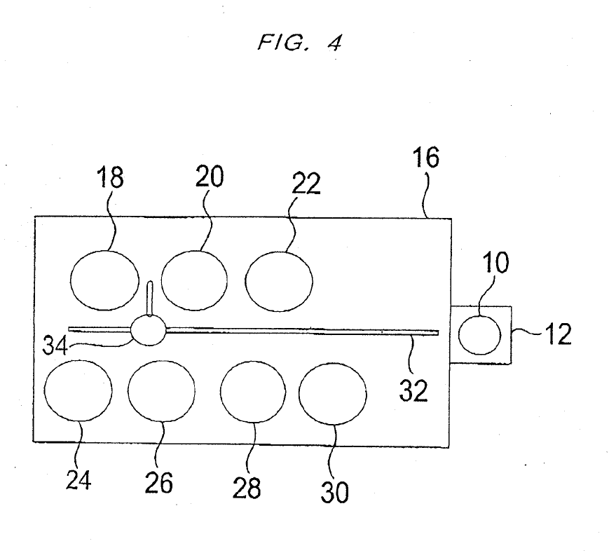

FIG. 4 shows an example of a semiconductor manufacturing apparatus used for selectively forming an interconnect protective film (alloy film) 50 on exposed surfaces of interconnects 48, as shown in FIG. 3A. As shown in FIG. 4, this semiconductor manufacturing apparatus has a loading/unloading unit 12 for placing and receiving a substrate cassette 10 housing substrates having interconnects 48. A first pre-processing unit 18 for performing a pre-plating process of a substrate, i.e., for cleaning a surface of a substrate, a second pre-processing unit 20 for imparting a catalyst to surfaces of cleaned interconnects 48 to activate the surfaces, and an electroless plating unit 22 for depositing an interconnect protective film (alloy film) 50 on the surface (surface to be processed) of the substrate W by performing an electroless plating process are disposed in series along one of long sides of a rectangular housing 16 having an exhaust system.

A post-processing unit 24 for performing a post-processing of the substrate to improve the selectivity of an interconnect protective film 50 formed on the surface of the substrate by the electroless plating process, a drying unit 26 for drying the substrate after the post-processing, a heat treatment unit 28 for performing a heat treatment (annealing) to the dried substrate W, and a film thickness measurement unit 30 for measuring a film thickness of an interconnect protective film 50 are disposed in series along the other of the long sides of the housing 16. Further, a transfer robot 34 movable along a rail 32 in parallel to the long sides of the housing 16 and for transferring a substrate between these units and the substrate cassette 10 placed on the loading/unloading unit 12 is disposed so as to be interposed between these units linearly arranged.

The housing 16 is shielded so as not to allow a light to transmit therethrough, thereby enabling subsequent processes to be performed under a light-shielded condition in the housing 16. Specifically, the subsequent processes can be performed without irradiating the interconnects with a light such as an illuminating light. By thus preventing the interconnects from being irradiated with a light, it is possible to prevent the interconnects of copper from being corroded due to a potential difference of light that is caused by application of light to the interconnects composed of copper, for example.

Next, a series of processing by this semiconductor manufacturing apparatus will be described.

First, a dried substrate W, having interconnects 48 formed in a surface thereof, shown in FIG. 2C is taken by the transfer robot 34 out of the substrate cassette 10, which houses substrates W in a state such that front surfaces of the substrates W face upward (in a face-up manner), placed on the loading/unloading unit 12, and is transferred to the first pre-processing unit 18. In the first pre-processing unit 18, the substrate W is held face down, and a cleaning process (cleaning with chemical liquid) is performed as a pre-plating process on a surface of the substrate W. Specifically, a chemical liquid such as a dilute H₂SO₄ solution, for example, at a temperature of 25° C., is sprayed toward the surface of the substrate W to remove CMP residues, such as copper, remaining on a surface of an insulating film 42 and oxides on the interconnects 48. Thereafter, the surface of the substrate W is rinsed (cleaned) with a rinsing liquid, such as pure water, to remove a cleaning chemical liquid remaining on the surface of the substrate W.

Usable chemical liquids include an inorganic acid with a pH of not more than 2, such as hydrofluoric acid, sulfuric acid or hydrochloric acid; an acid with a pH of not more than 5 and having chelating ability, such as formic acid, acetic acid, oxalic acid, tartaric acid, citric acid, maleic acid or salicylic acid; and an acid with a pH of not more than 5 to which is added a chelating agent such as a halide, a carboxylic acid, a dicarboxylic acid, an oxycarboxylic acid, or a water-soluble salt thereof. By carrying out cleaning of the substrate with such chemical liquids, the CMP residues, such as copper, remaining on the insulating film 42 and oxides in the surfaces of interconnects (plating base) can be removed, whereby plating selectivity and adhesion of a plated film to a base can be enhanced.

Next, the substrate W after the cleaning process and the rinsing process is transferred to the second pre-processing unit 20 by the transfer robot 34. In the second pre-processing unit 20, the substrate W is held face down, and a catalyst impartation process is performed on the surface of the substrate W. Specifically, a mixed solution of PdCl₂/HCl or the like, for example at a temperature of 25° C., is ejected toward the surface of the substrate W to adhere Pd as a catalyst to the surfaces of the interconnects 48. More specifically, Pd cores are formed as catalyst cores (seeds) on the surfaces of the interconnects 48 to activate exposed surfaces of the interconnects 48. Then, a catalyst chemical liquid remaining on the surface of the substrate W is rinsed (cleaned) with a rinsing liquid such as pure water.

Thus, when a catalyst is imparted to the surface of the substrate W, it is possible to enhance the selectivity of electroless plating. Various materials can be used as a catalyst metal. However, it is desirable to use Pd in view of a reaction rate, easiness of the control, or the like.

The substrate W after the catalyst impartation and rinsing is transferred by the transfer robot 34 to the electroless plating unit 22, where the substrate W is held face down to carry out electroless plating process of the surface of the substrate. In particular, the substrate W is immersed in a CoWP plating solution, e.g., at a temperature of 85° C., e.g., for about 120 seconds to carry out selective electroless plating (electroless CoWP cap plating) of the activated surfaces of interconnects 48, thereby selectively forming an interconnect protective film (cap material) 50.

In the electroless plating is used a processing solution (electroless plating solution) having a pH of 8.0 to 9.5, comprising Co, W, and a P-containing reducing agent in a molar concentration ratio of 1:(0.5 to 4.0):(1 to 15).

The use of the processing solution allows the interconnect protective film (alloy film) 50, deposited by plating reaction, to contain W in an amount of 1 to 9 atomic %. This can reduce a difference in the material supply rate, caused by the density, etc. of the interconnect pattern of the substrate, during the plating reaction, thus reducing a difference in the film-forming rate and, in addition, increase the thermal stability of the interconnect protective film 50 and prevent impurities, such as oxygen and copper, from permeating and diffusing through the interconnect protective film 50. The use of the processing solution also allows the interconnect protective film 50, deposited by the plating reaction, to contain P in an amount of 3 to 12 atomic %. The presence of P in such an amount around Co can prevent impurities from diffusing out of the interconnect protective film 50, enabling the interconnect protective film 50 to function as an oxidation resistant film or an interconnect metal diffusion-preventing film. There is a case where the interconnect protective film 50 forms a compound with an impurity. This increases the function of the interconnect protective film 50, e.g., as an oxidation resistant film.

The content of sodium in the processing solution is preferably not more than 1 g/L, and the content of ammonia or a salt thereof and/or an organic alkali or a salt thereof in the processing solution is preferably not more than 0.1 mol/L.

In general, components of an electroless plating solution are used in the form of an alkali metal salt or an ammine salt, and an aqueous solution of KOH, NaOH, Ca(OH)₂, ammonia or an organic alkali, as typically exemplified by TMAH (tetramethylammonium hydroxide), is used as a pH adjustment agent. Sodium, when it diffuses into a semiconductor element, can change the properties of the semiconductor element. Further, sodium, as compared to, e.g., potassium, is more likely to form a stable complex with a counter ion, whereby a deposit is likely to be produced when the solution temperature is lowered (the solubility of the complex is low). Ammonia, on the other hand, forms a stable complex with a metal in the plating solution, which retards the initiation of reaction and eventually shortens the life of the plating solution. Further, the volatility of ammonia may require a troublesome control of the solution.

A stable process becomes possible by making the content of sodium in the processing solution not more than 1 g/L and using, e.g., potassium instead. A stable process also becomes possible by making the content of an ammonium salt and/or tetramethyl ammonium hydroxide not more than 0.1 mol/L and using, e.g., potassium as a counter ion.

The processing solution preferably contains a citrate or a tartrate, and boric acid or a tetraborate. By using, as a complexing agent for a metal, a citrate or a tartrate, i.e., a carboxylic acid, which does not contain ammonia in a large proportion, a complex, when heated continuously, can be prevented from changing its form, enabling stable deposition. Boric acid or a tetraborate shows a pH buffering action at a reaction interface in a bath in which ammonia is little present. The use of boric acid or a tetraborate in the processing solution can therefore provide a stable plating reaction.

The citrate or the tartrate preferably has potassium as a counter ion, and the tetraborate also preferably has potassium as a counter ion. A citrate, etc., having sodium as a counter ion, generally has a low solubility and can possibly be crystallized in the processing solution. A citrate, etc., having ammonia as a counter ion, generally has a low boiling point, and thus can vaporize when the solution is heated. A troublesome control of the processing solution is therefore needed. On the other hand, the use of potassium as a counter ion of a citrate, etc. makes it possible to carry out stable plating with good reproducibility.

The processing solution preferably further contains a hypophosphite. Phosphinic acid (hypophosphorous acid) in an electroless plating solution principally acts as a reducing agent. DMAB (dimethylamine borane) and hydrazine are generally known as a reducing agent for electroless plating. DMAB and hydrazine are, however, generally poor in the stability in a plating solution, which may shorten the life of the solution. Phosphinic acid, on the other hand, is relatively stable in a plating solution. Thus, the use of phosphinic acid as a reducing agent can extend the life of the solution. When it is intended to intentionally extend the life of a plating solution, an organic compound called stabilizer may be added to the solution. Specifically, a sulfur-containing organic compound, such as thiodipropionic acid, thiodiglycolic acid, thiourea, 2-aminothiazole or mercaptobenzothiazole, may be used in an amount of not more than 100 ppm. A nitrogen-containing organic compound, such as bipyridyl or phenanthroline, can also be used. The use of such a stabilizer can extend the life of an electroless plating solution containing Co, Ni, Cu, etc. as main metal ion species.

The hypophosphite preferably is an aqueous solution of phosphinic acid whose counter ion is hydrogen ion. Sodium phosphinate and ammonium phosphinate are generally known as a salt to supply phosphinate (hypophosphite) ion. As described above, these salts have the solubility and semiconductor contamination problems (with sodium) and the problem of the life of bath (with ammonia). The use of an aqueous solution of phosphinic acid (phypophosphorous acid) H₃PO₂, which does not contain a counter ion (whose counter ion is hydrogen ion), can prepare a bath that can deal with the above problems.

The film-forming rate of the interconnect protective film (alloy film) 50 in electroless plating is preferably 1 to 40 nm per minute. The film-forming rate is directly related to the productivity, and therefore cannot be made too low. Too high a film-forming rate, on the other hand, cannot ensure the uniformity and the reproducibility of the interconnect protective film 50. A thickness of at least about 5 nm is needed to meet the intended objective of the interconnect protective film 50, whereas the film thickness should not exceed about 50 nm from the viewpoint of minimizing an increase in the resistance of interconnects. Therefore, the film-forming rate is generally 1 to 40 nm per minute, preferably 2 to 10 nm per minute.

The temperature of the processing solution upon contact with the surfaces of interconnects 48 as a base is preferably 50 to 90° C. The reactivity of the processing solution at such a temperature can be kept constant, providing the interconnect protective film (alloy film) 50 with excellent in-plane thickness uniformity. The temperature of the processing solution is more preferably 60 to 75° C.

Various types of electroless plating solutions can be used for forming the interconnect protective film 50 that selectively covers the exposed surfaces of interconnects 48 to protect the interconnects 48, and any plating solution needs to be heated. The use of a plating solution at a temperature of less than 50° C. cannot obtain a sufficient film-forming rate, whereas the use of a plating solution at a temperature of more than 90° C. will cause a too high film-forming rate and considerable evaporation of moisture, making stable film formation difficult. By bringing a plating solution set at 50 to 90° C. into contact with a substrate upon electroless plating, film formation can be carried out with good reproducibility.

After pulling up the substrate W from the plating solution, a stop liquid, which is a neutral liquid having a pH of 6 to 7.5, is brought into contact with the surface of the substrate W, thereby stopping electroless plating. By thus stopping the plating reaction promptly after pulling up the substrate W from the plating solution, the plated film can be prevented from becoming uneven. The time for the treatment with the stop liquid is preferably from 1 to 5 seconds. The stop liquid may be exemplified by pure water, hydrogen gas-dissolved water or electrolytic cathode water. The interconnect material can corrode due to local cell effect, etc. depending on the surface material. Such a problem can be avoided by stopping plating with ultrapure water that is made reductive.

Thereafter, the plating solution remaining on the substrate is rinsed (cleaned) with a rinsing liquid, such as pure water. The interconnect protective film 50 of CoWP alloy is thus formed selectively on the surfaces of interconnects 48 to protect the interconnects 48.

Next, the substrate W after the electroless plating is transferred by the transfer robot 34 to the post-processing unit 24, where the substrate W is subjected to post-plating processing to enhance the selectivity of the interconnect protective film (alloy film) 50 formed on the surface of the substrate W and to thereby increase the yield. In particular, while applying a physical force to the surface of the substrate W, for example, by roll scrub cleaning or pencil cleaning, a chemical solution containing one or more of a surfactant, an organic alkali and a chelating agent is supplied to the surface of the substrate W to thereby completely remove plating residues, such as fine metal particles, on the interlevel dielectric film 42, thus enhancing the selectivity of plating. The use of such a chemical solution can more effectively enhance the selectivity of electroless plating. The surfactant preferably is a nonionic one, the organic alkali preferably is a quaternary ammonium compound or an amine, and the chelating agent preferably is ethylenediamine or its derivative or an organic acid.

When such a chemical solution is employed, the chemical solution remaining on the surface of the substrate W is rinsed off (cleaned) with a rinsing liquid, such as pure water. The rinsing liquid may be exemplified by pure water, hydrogen gas-dissolved water and electrolytic cathode water. As described above, the interconnect material can corrode due to local cell effect, etc. depending on the surface material. Such a problem can be avoided by carrying out rinsing of the substrate with ultrapure water that is made reductive.

Besides the above-described roll scroll cleaning or pencil cleaning which effects cleaning through a physical force, it is also possible to employ cleaning with a complexing agent, uniform etching back with an etching liquid, etc., or a combination thereof to completely remove residues remaining on the interlevel dielectric film.

The substrate W after the post-processing is transferred by the transfer robot 34 to the drying unit 26, where the substrate W is rinsed, according to necessity, and is then spin-dried by rotating it at a high speed.

The series of processings for forming the interconnect protective film 50 by electroless plating on the exposed surfaces of embedded interconnects 48 formed in the surface of the substrate W can thus be carried out successively. Further, since the substrate is finished in the dried state, the substrate can be sent directly to the next process step. This can inhibit deterioration of the interconnect protective film (alloy film) 50 during the period of time until the initiation of the next step.

When carrying out drying (spin-drying) of the substrate W to bring it into the dried state, it is preferred to use dry air or a dry inert gas so as to control the ambient humidity around the substrate. If drying of the substrate is carried out under normal atmospheric conditions, the moisture on the substrate will scatter into the ambient atmosphere to thereby increase the humidity. Accordingly, there will be a considerable amount of moisture adsorbed on the substrate surface even after drying, which can cause problems, such as oxidation of the interconnects by the adsorbed moisture. Further, a mist generated upon spin-drying of the substrate can produce problematic water marks on the substrate. Such drawbacks can be obviated by controlling the ambient humidity around the substrate upon its drying by using dry air or dry nitrogen gas.

The substrate W after spin-drying is transferred by the transfer robot 34 to the heat treatment unit 28, where the substrate W after the post-processing is subjected to heat treatment (annealing) for modification of the interconnect protective film 50. Taking account of a practical processing time, the temperature necessary for modification of the interconnect protective film 50 is at least 120° C. Also taking account of the heat resistances of the materials constituting the device, the heating temperature is desirably not higher than 450° C. Accordingly, the temperature for the heat treatment (annealing) is, for example, 120 to 450° C. By thus heat-treating the substrate W, the barrier properties of the interconnect protective film 50 formed on the exposed surfaces of interconnects 48 and its adhesion to the interconnects 48 can be enhanced.

Next, the substrate W after the heat treatment is transferred by the transfer robot 34 to the film thickness measurement unit 30, for example, of an optical, AFM or EDX type. The thickness of the interconnect protective film 50 formed on the surfaces of interconnects 48 is measured with the film thickness measurement unit 30, and the substrate W after the measurement of the film thickness is returned by the transfer robot 34 to the substrate cassette 10 set in the loading/unloading unit 12.

The results of on-line or off-line measurement of the thickness of the interconnect protective film 50 formed on the exposed surfaces of interconnects 48 are fed back prior to electroless plating of the next substrate. Thus, based on a change in the film thickness, the processing time for plating of the next substrate, for example, is adjusted. In this manner, the thickness of the interconnect protective film 50 formed on the exposed surfaces of interconnects 48 can be controlled at a constant value.

Prior to the step of cleaning the exposed surfaces of interconnects 48 before the selective formation thereon of the interconnect protective film 50, it is preferred to carry out flattening of the exposed surfaces of interconnects 48 by any one of chemical mechanical polishing, electrochemical polishing and composite electrochemical polishing. This can provide a flatter interconnect protective film 50.

While the formation of the CoWP alloy film by the use of the processing solution for electroless CoWP plating has been described, it is also possible to use Ni instead of Co, Mo instead of W, and B instead of P, respectively.

### Example 1

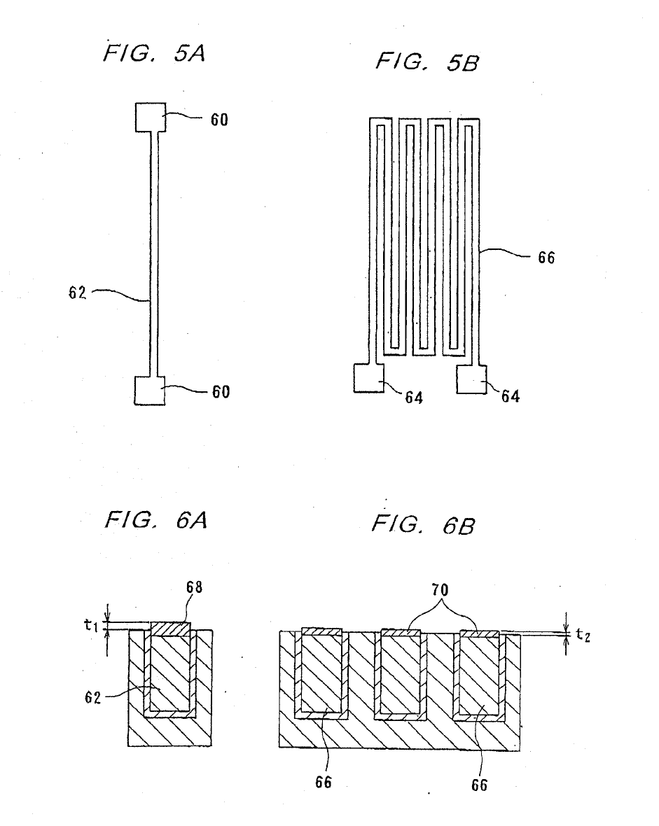

A 200 mm wafer, in which an isolated interconnect 62 of copper having a length of about 3 mm and a width of 0.25 μm, linearly connecting pads 60, 60, as shown in FIG. 5A, and a dense interconnect 66 of copper, having a length of about 300 mm and a width of 0.25 μm, arranged parallel with a spacing of 0.25 μm and connecting pads 64, 64, as shown in FIG. 5B, are co-present, was prepared as a test sample. The interconnects 62, 66 were formed by forming a barrier layer of Ta and a copper seed layer by sputtering over the wafer surface with interconnect recesses formed therein, and then filling copper into the recesses by electroplating, followed by CMP to flatten the surface.

First, the sample was cut, and the cut sample was immersed in oxalic acid (2 wt %) at room temperature for one minute, followed by cleaning with pure water. The sample was then subjected to catalyst treatment by immersing it in a mixed solution of 0.1 g/L PdCl₂ and 0.1 M HCl for 30 seconds, followed by cleaning with pure water. Thereafter, the sample was immersed in a heated plating solution (processing solution) having the below-described composition for two minutes to form an alloy film (interconnect protective film) on the surfaces of the interconnects, followed by cleaning with pure water and drying. The cross section of the sample after processing was observed with SEM and evaluated. The heights of those portions of the alloy film, which protrude from the surface interlevel dielectric film, were determined as the thicknesses of the alloy film. The composition of the alloy film was determined by dissolving the sample in aqua regia and analyzing the solution by ICP emission spectrometry.

Composition of plating solution (mol/L)

| | |
|---|---|
| CoSO₄•7H₂O | 0.05 |
| K₃C₆H₅O₇•H₂O | 0.3 |
| H₃BO₃ | 0.55 |
| K₂WO₄ | 0.002 |
| H₃PO₂ (aqueous solution) | 0.1 |
| pH | 9.0 |

As a result, an alloy film 68 having a thickness t₁ of 40 nm was formed on a surface of the isolated interconnect 62, as shown in FIG. 6A, while an alloy film 70 having a thickness t₂ of 20 nm was formed on a surface of the dense interconnect 66, as shown in FIG. 6B. The film thickness ratio t₁:t₂ is 2:1 (t₁:t₂=2:1), which ratio indicates a significant improvement over conventional ones (e.g., about 6.5:1). The composition Co:W:P (atomic %) of the alloy film was found to be 89:4:7 (Co:W:P (atomic %)=89:4:7).

### Example 2

The same sample as in Example 1 was prepared, and an alloy film (interconnect protective film) was formed on the interconnects in the same manner as in Example 1, except for using a plating solution (processing solution) having the below-described composition. The thickness and the composition of the alloy film were determined in the above-described manner.

Composition of plating solution (mol/L)

| | |
|---|---|
| CoSO₄•7H₂O | 0.05 |
| K₃C₆H₅O₇•H₂O | 0.3 |
| H₃BO₃ | 0.55 |
| K₂WO₄ | 0.002 |
| H₃PO₂ (aqueous solution) | 0.2 |
| pH | 9.0 |

As a result, the thickness t₁ of the alloy film 68 formed on the surface of the isolated interconnect 62, shown in FIG. 6A, was found to be 100 nm, while the thickness t₂ of the alloy film 70 formed on the surface of the dense interconnect 66, shown in FIG. 6B, was found to be 20 nm. The film thickness ratio t₁:t₂ is 5:1 (t₁:t₂=5:1), which ratio indicates an improvement over conventional ones (e.g., about 6.5:1). The composition Co:W:P (atomic %) of the alloy film was found to be 88:2:10 (Co:W:P (atomic %)=8:2:10).

### INDUSTRIAL APPLICABILITY

The present invention is useful for a semiconductor device having a conductive film, which has a function of preventing thermal diffusion of an interconnect material into an interlevel dielectric film or a function of enhancing adhesion between interconnects and an interlevel dielectric film, on bottoms and sides surfaces or exposed surfaces of embedded interconnects of an interconnect material embedded in interconnect recesses provided in a surface of a substrate, or having an interconnect protective film, such as a magnetic film, for covering the interconnects.

1. A method for manufacturing a semiconductor device, comprising:
carrying out pre-plating processing on a surface of a base; and
forming an alloy film by bringing a processing solution for electroless plating into contact with the surface of the base after the pre-plating processing, said processing solution having a pH of 8.0 to 9.5 and comprising nickel or cobalt, tungsten or molybdenum, and a phosphorus- or boron-containing reducing agent in a molar concentration ratio of 1:(0.5 to 4.0):(1 to 15).

2. The method according to claim 1, wherein the pre-plating processing is carried out on surfaces of embedded interconnects as the base, formed by filling an interconnect material into interconnect recesses formed in an electric insulator on a substrate.

3. The method according to claim 1, wherein the content of sodium in the processing solution is not more than 1 g/L.

4. The method according to claim 1, wherein the content of ammonia or a salt thereof and/or an organic alkali or a salt thereof in the processing solution is not more than 0.1 mol/L.

5. The method according to claim 1, wherein the temperature of the processing solution upon contact with the surface of the base is 50 to 90° C.
